(19) United States
(12) Patent Application Publication
(10) Pub. No.: US 2020/0313022 A1
(43) Pub. Date: Oct. 1, 2020

(54) SINGLE PHOTON DETECTOR AND MANUFACTURING METHOD THEREOF

(71) Applicant: ELECTRONICS AND TELECOMMUNICATIONS RESEARCH INSTITUTE, Daejeon (KR)

(72) Inventor: Jae-Sik SIM, Sejong-si (KR)

(73) Assignee: ELECTRONICS AND TELECOMMUNICATIONS RESEARCH INSTITUTE, Daejeon (KR)

(21) Appl. No.: 16/703,120

(22) Filed: Dec. 4, 2019

(30) Foreign Application Priority Data
Mar. 25, 2019 (KR) 10-2019-0033876

(51) Int. Cl. H01L 31/107; H01L 31/18; H01L 31/0352; H01L 31/0224; H01L 31/0232

(52) U.S. Cl. CPC H01L 31/107; H01L 31/1844; H01L 31/03046; H01L 31/022416; H01L 31/02327; H01L 31/03529

(57) ABSTRACT

Provided is a single photon detector. The single photo detector includes a substrate of a first conductivity type, a light absorption layer on the substrate, a grading layer and an electric field buffer layer sequentially stacked on the light absorption layer, an impurity region of a second conductivity type disposed in the electric field buffer layer and opposite the first conductivity type, a first electrode disposed on the electric field buffer layer and electrically connected to the impurity region, a reflective layer disposed between the light absorption layer and the substrate, and a second electrode disposed below the substrate and electrically connected to the substrate.

### CROSS-REFERENCE TO RELATED APPLICATIONS

This U.S. non-provisional patent application claims priority under 35 U.S.C. § 119 of Korean Patent Application No. 10-2019-0033876, filed on Mar. 25, 2019, the entire contents of which are hereby incorporated by reference.

### BACKGROUND

The present disclosure herein relates to a single photon detector and a manufacturing method thereof.

A single photon avalanche diode (SPAD) is an element used as a single photon detector in a variety of applications such as quantum key distribution (QKD) for quantum encryption communication, optical time domain reflectometry (OTDR), and laser radar (LADAR).

Typical avalanche photodiodes used as receivers for optical communications may operate at bias voltages lower than the breakdown voltage to obtain optical current proportional to the input optical power. That is, in linear mode operation, the gain is about 10 to 100 times.

On the other hand, single photon avalanche diodes operate at a voltage higher than the breakdown voltage, i.e. in Geiger mode, to generate a detectable magnitude of current with gains of more than 10,000 times through avalanche amplification of carriers excited by single photons.

### SUMMARY

The present disclosure provides a single photon detector that can increase a detection efficiency.

The present disclosure also provides a method of manufacturing a single photon detector that can be easily embodied.

An embodiment of the inventive concept provides a single photon detector including: a substrate of a first conductivity type; a light absorption layer on the substrate; a grading layer and an electric field buffer layer sequentially stacked on the light absorption layer; an impurity region of a second conductivity type disposed in the electric field buffer layer and opposite the first conductivity type; a first electrode disposed on the electric field buffer layer and electrically connected to the impurity region; a reflective layer disposed between the light absorption layer and the substrate; and a second electrode disposed below the substrate and electrically connected to the substrate.

In an embodiment, the reflective layer may be a distributed Bragg reflector.

In an embodiment, the reflective layer may comprise a structure in which a first film and a second film of different materials are alternately stacked, and each of the first film and the second film is selected from InP, InGaAs, InGaAsP, InAlAs, AlGaAs, and InAlGaAs.

In an embodiment, the reflective layer may have a reflectance of 90% or more.

In an embodiment, the single photon detector may further include a buffer layer interposed between the reflective layer and the light absorption layer, wherein the buffer layer may include the same material as the substrate.

In an embodiment, the single photon detector may further include an electric field control layer interposed between the grading layer and the electric field buffer layer, wherein the electric field control layer may include silicon.

In an embodiment, the single photon detector may further include a guard ring region of the second conductivity type disposed to be spaced apart from the impurity region in the electric field buffer layer, wherein the guard ring region and the first electrode may have a ring shape in a plan view.

In an embodiment, the single photon detector may further include an ohmic pattern disposed between the first electrode and the impurity region, wherein the ohmic pattern may have a ring shape in a plan view.

In an embodiment, the ohmic pattern may be doped with zinc.

In an embodiment, the single photon detector may further include a passivation film covering an upper surface of the electric field buffer layer, wherein the first electrode may be electrically connected to the impurity region through the passivation film, wherein the first electrode may have a circular shape in a plan view and be transparent.

In an embodiment, the first electrode may include an adhesive layer, a diffusion barrier layer, and an electrode pattern that are sequentially stacked.

In an embodiment of the inventive concept, a manufacturing method of a single photon detector includes: forming a reflective layer on a substrate of a first conductivity type; forming a light absorption layer on the reflective layer; forming a grading layer on the light absorption layer; forming an electric field control layer on the grading layer; forming an electric field buffer layer on the electric field control layer; forming an impurity region of a second conductivity type opposite the first conductivity type in the electric field buffer layer; and forming a first electrode electrically connected to the impurity region on the electric field buffer layer.

In an embodiment, the forming of the reflective layer may include performing a plurality of times a process cycle including forming a first film and forming a second film, wherein each of the first film and the second film may be selected from InP, InGaAs, InGaAsP, InAlAs, AlGaAs, and InAlGaAs, and the first film may include a material different from a material of the second film.

In an embodiment, the method may further include forming a buffer layer interposed between the reflective layer and the light absorption layer, wherein the buffer layer may include the same material as the substrate.

In an embodiment, the electric field control layer may include silicon.

In an embodiment, the forming of the impurity region may include: sequentially stacking a first diffusion control layer, a second diffusion control layer, and a mask layer on the electric field buffer layer; patterning the mask layer and the second diffusion control layer to form a second diffusion control pattern and a mask pattern including a first opening exposing the first diffusion control layer; forming an impurity containing layer in contact with the first diffusion control layer in the first opening; and performing a heat treatment process to diffuse the impurities contained in the impurity containing layer into the electric field buffer layer through the first diffusion control layer.

In an embodiment, the method may further include forming a capping layer covering the impurity containing layer before the heat treatment process.

In an embodiment, the method may further include, after the forming of the impurity region, removing the mask pattern and the second diffusion control pattern; and patterning the first diffusion control layer to form an ohmic pattern.

In an embodiment, the method may further include forming a guard ring region of the second conductivity type to be spaced apart from the impurity region in the electric field buffer layer, wherein the forming of the guard ring region may be performed simultaneously with the forming of the impurity region.

In an embodiment, the method may further include: removing a portion of a lower part of the substrate; and forming a second electrode on the lower surface of the substrate.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a plan view of a single photon detector according to embodiments of the inventive concept;

FIG. 2A is a cross-sectional view taken along line A-A′ of FIG. 1;

FIG. 2B is an enlarged view of ‘P1’ of FIG. 2A;

FIG. 2C is an enlarged view of ‘P2’ of FIG. 2A;

FIGS. 3 to 10 are cross-sectional views sequentially illustrating a process of manufacturing a single photon detector having a cross section of FIG. 2A according to embodiments of the inventive concept; and

FIGS. 11 and 12 are cross-sectional views of a single photon detector according to embodiments of the inventive concept.

### DETAILED DESCRIPTION

Purposes, other purposes, features, and advantages of the inventive concept will be easily understood through preferred embodiments relating to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer (or film) is referred to as being ‘on’ another layer or substrate, it may be directly on the other layer or substrate, or intervening layers may also be present. Additionally, in the drawings, the thicknesses of components are exaggerated for effective description.

Additionally, embodiments described in this specification will be described with plan views and/or sectional views, that is, ideal exemplary views of the inventive concept. In the drawings, the thicknesses of a layer and an area are exaggerated for effective description. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. For example, an etched region illustrated as a rectangle may have rounded or curved features. Therefore, areas exemplified in the drawings have general properties, and are used to illustrate a specific shape of a device region. Thus, this should not be construed as limited to the scope of the inventive concept. It will be understood that the terms “first” and “second” are used herein to describe various components but these components should not be limited by these terms. These terms are just used to distinguish a component from another component. Embodiments described herein include complementary embodiments thereof.

The terms used in this specification are used only for explaining specific embodiments while not limiting the inventive concept. The terms of a singular form may include plural forms unless referred to the contrary. The meaning of “comprises,” and/or “comprising” in this specification specifies the mentioned component but does not exclude at least one another component.

Hereinafter, embodiments of the inventive concept are described in more detail with reference to the accompanying drawings.

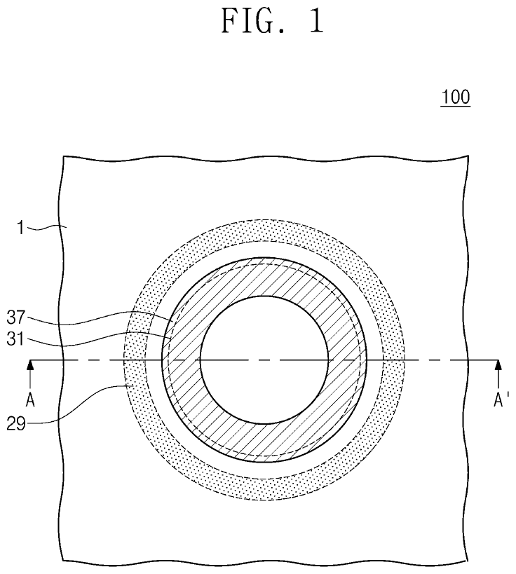

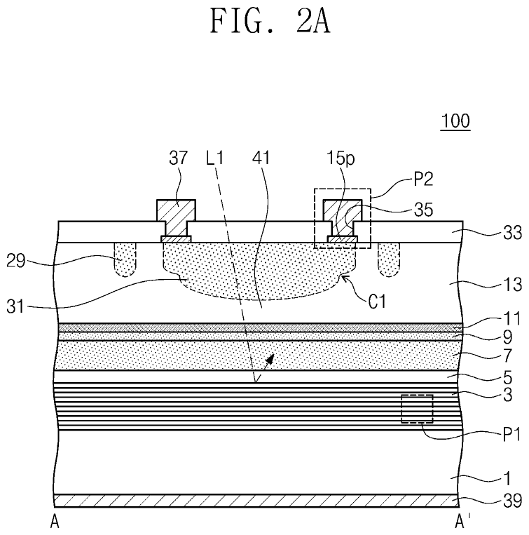

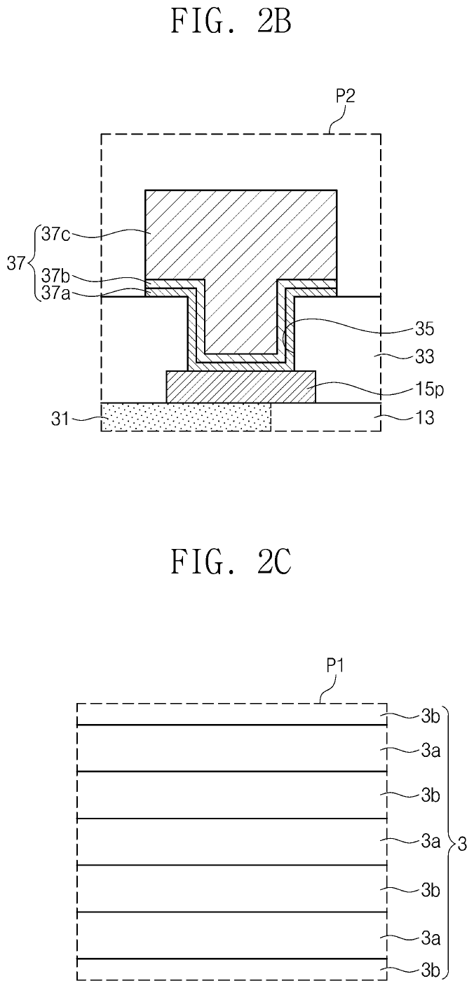

FIG. 1 is a plan view of a single photon detector according to embodiments of the inventive concept. FIG. 2A is a cross-sectional view taken along line A-A′ of FIG. 1. FIG. 2B is an enlarged view of ‘P1’ of FIG. 2A. FIG. 2C is an enlarged view of ‘P2’ of FIG. 2A.

Referring to FIGS. 1 and 2A to 2C, the single photon detector 100 according to the present example may include a substrate 1. The substrate 1 may be, for example, a first conductivity type. The first conductivity type may be, for example, an n-type. The substrate 1 may include, for example, n-type InP. The reflective layer 3 is disposed on the substrate 1. The reflective layer 3 may be, for example, a distributed Bragg reflector. The distributed Bragg reflector may be formed by periodically changing the characteristics of a multilayer or a dielectric waveguide of a cross material of a material having various refractive indices to periodically change the effective refractive index.

The reflective layer 3 may have a reflectance of about 90% or more. The reflective layer 3 may have, for example, a structure in which the first film 3a and the second film 3b are alternately stacked. The first film 3a and the second film 3b may include different materials. The first film 3a and the second film 3b may be selected from InP, InGaAs, InGaAsP, InAlAs, AlGaAs, and InAlGaAs, respectively. Atom contents of the InP, InGaAs, InGaAsP, InAlAs, AlGaAs, and InAlGaAs may be different. For example, the InAlGaAs may include InAl_{0.18}Ga_{0.30}As. The combination (first film/second film) of the first film 3a and the second film 3b may be, for example, one of InP/InGaAsP, InAlGaAs/InAlAs, InP/InAlGaAs, InAlAs/InAl₀₁₈Ga_{0.30}As, InP/InAlAs, InP/AlGaAs, InP/InAlAs/InAl_{0.18}Ga_{0.30}As, InGaAs/InAlAs, InGaAs/InP, and InP/InGaAs. The effective refractive index of the InP/InGaAsP may be about 0.27. The effective refractive index of the InAlGaAs/InAlAs may be about 0.3. The effective refractive index of the InP/InAlGaAs may be about 0.34. The first film 3a and the second film 3b adjacent to each other may form a pair of layers, and reflectance may vary according to the number of layers. For example, as a result of simulating the communication wavelength of 1500 nm, when 40 layers of InAlAs/InAl_{0.18}Ga_{0.30}As were grown, the reflectance of the maximum was 98%. In addition, when InP/InGaAs was grown to 20 to 40 layers, the result of the simulation for 1500 nm showed a reflectance of about 94%.

A buffer layer 5 may be disposed on the reflective layer 3. The buffer layer 5 may include the same material as the substrate 1. For example, the buffer layer 5 may be n-type InP. The light absorption layer 7 may be disposed on the buffer layer 5. The light absorption layer 7 may include undoped InGaAs. A grading layer 9, an electric field control layer 11, and an electric field buffer layer 13 may be sequentially stacked on the light absorption layer 7. The grading layer 9 may have a structure for filling a band gap difference between the light absorption layer 7 and the electric field control layer 11. In detail, the grading layer 9 may have a structure in which InGaAsP having various band gaps are sequentially stacked in multiple layers. The grading layer 9 may have a quantum well or a superlattice structure.

The electric field control layer 11 may be of the first conductivity type. The electric field control layer 11 may be n-type, for example. The electric field control layer 11 may be doped with silicon (Si), for example. The electric field control layer 11 may be InP doped with silicon. The electric field control layer 11 may have a thickness of about 0.01 μm to about 2.0 μm. The doping concentration of the silicon in the electric field control layer 11 may be about 1.0×10¹⁶ cm⁻³ to 1.0×10¹⁸ cm⁻³. The electric field buffer layer 13 may include, for example, InP. The electric field buffer layer 13 may or may not (or intrinsic) be of the first conductivity type.

An impurity region 31 may be disposed in the electric field buffer layer 13. The impurity region 31 may have a circular shape in a plan view. The impurity region 31 may be a region doped with impurities of a second conductivity type opposite to the first conductivity type. The impurity region 31 may be doped with, for example, P-type impurities. The impurity may be, for example, zinc (Zn). The impurity region 31 may include InGaAs doped with zinc. The impurity region 31 is formed to have a double diffusion effect by using a difference in diffusion depth according to the thicknesses of the first diffusion control layer and the second diffusion control layer, and the sidewalls of the impurity region may have an inflection point C1. Corner portions of the impurity region 31 may be more rounded by the inflection point C1. In such a way, this prevents edge breakdown in which the electric field is concentrated and the avalanche amplification occurs in advance, together with a guard ring region 29 that mitigates the electric field concentrated at the edge portion.

The guard ring region 29 spaced apart from the impurity region 31 may be disposed in the electric field buffer layer 13. The guard ring region 29 may have a shape of a circular ring in a plan view and may surround the impurity region 31. The guard ring region 29 may also be a region doped with impurities of the second conductivity type. For example, the guard ring region 29 may include zinc-doped InGaAs. The depth from the upper surface of the electric field buffer layer 13 to the lower end of the guard ring region 29 may be shallower than the depth from the upper surface of the electric field buffer layer 13 to the lower end of the impurity region 31.

An ohmic pattern 15p may be disposed at an edge of the upper end of the impurity region 31. The ohmic pattern 15p may include, for example, InGaAs. The ohmic pattern 15p may be doped with impurities of the second conductivity type. For example, the ohmic pattern 15p may be doped with zinc. The upper surface of the electric field buffer layer 13 may be covered with a passivation film 33. The passivation film 33 may be an insulating film that is transparent to allow light to pass through but has an antireflection function. The passivation film 33 may serve to prevent the leakage current from being electrically generated through the surface of the single photon detector and prevent the dark current value from being increased. The passivation film 33 may be formed of a silicon nitride film, polyimide, or Bisbenzocyclotene (BCB). The passivation film 33 may partially cover the edge of the ohmic pattern 15p. The passivation film 33 may include a first opening 35 exposing the upper surface of the ohmic pattern 15p.

The first electrode 37 may be electrically connected to the ohmic pattern 15p and the impurity region 31 through the first opening 35. The first electrode 37 may contain a metal. The ohmic pattern 15p may serve to lower (forward) electrical resistance as an ohmic contact between the first electrode 37 containing a metal and the impurity region 31 including a semiconductor material. The first electrode 37 and the ohmic pattern 15p may have a circular ring shape in a plan view.

In detail, the first electrode 37 may include an adhesive film 37a, a diffusion barrier film 37b, and an electrode pattern 37c that are sequentially stacked. The adhesive film 37a may include titanium (Ti). The adhesive film 37a may be in contact with the sidewall of the first opening 35 and the upper surface of the ohmic pattern 15p. The diffusion barrier film 37b may include platinum (Pt). The electrode pattern 37c may include gold (Au).

The second electrode 39 may be disposed on the lower surface of the substrate 1. The second electrode 39 may be in contact with the substrate 1. The second electrode 39 may include an alloy of gold and at least one selected from nickel, chromium, and germanium.

A portion located below the impurity region 31 in the electric field buffer layer 13 may be referred to as an amplification layer 41. That is, the amplification layer 41 may be defined as part of the electric field buffer layer 13 interposed between the impurity region 31 and the electric field control layer 11. The amplification layer 41 may have a thickness of 0.2 μm to 2.0 μm.

The single photon detector 100 may operate at a bias voltage higher than the breakdown voltage. Since it operates in an unstable breakdown system, a single photon (or one dark current electron) may cause an important avalanche of the charge. The photon detection efficiency of the single photon detector 100 may be determined by the photon absorption probability, the probability that the charge excited by the photonic agent is injected into the amplification layer 41, and the probability of occurrence of avalanche amplification by the injected charge. Although avalanche amplification occurrence probability increases in proportion to the bias voltage, there is a problem in that a dark count may also increase. Therefore, in order to obtain high photon detection efficiency at low bias voltage, it is necessary to increase photoresponse, which is a photon absorption probability. To this end, a reflective layer 3 for reflecting light L1 incident into the single photon detector 100 is required. In particular, when the reflective layer 3 is a distributed Bragg reflector, it may have a high reflectance of 90% or more as described above. As a result, the light L1 enters the substrate 1 and minimizes photons exiting to the outside, and reflects the light L1 to the light absorption layer 7 to increase photon/charge detection efficiency. In addition, the simulation may optimize the internal reflectance by optimizing the material combinations and the number of stacked layers of the distributed Bragg reflector so that the detection efficiency of the single photon detector 100 may be further increased.

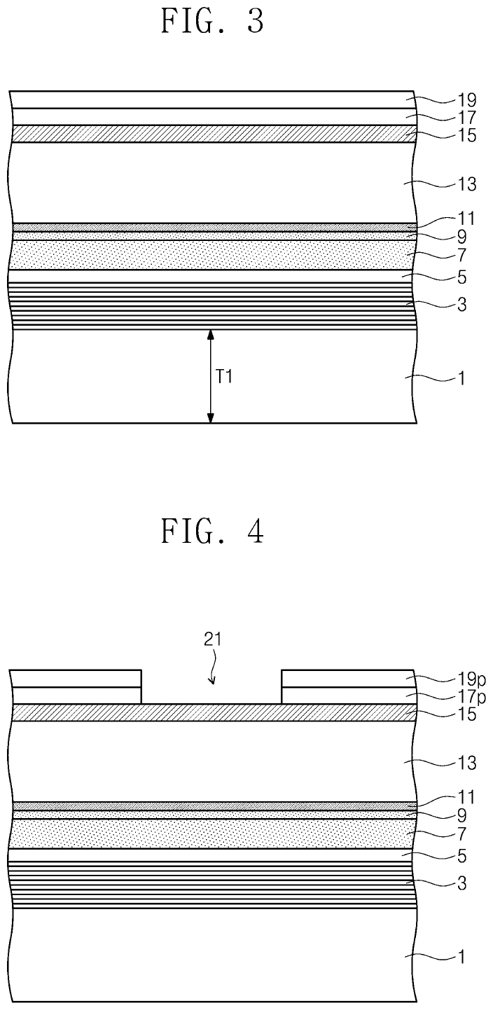

FIGS. 3 to 10 are cross-sectional views sequentially illustrating a process of manufacturing a single photon detector having a cross section of FIG. 2A according to embodiments of the inventive concept.

Referring to FIG. 3, a substrate 1 may be prepared. The substrate 1 may be, for example, n-type InP. The substrate 1 may be formed with a first thickness T1. A reflective layer 3 may be formed on the substrate 1. Forming the reflective layer 3 may include performing a plurality of times a process cycle including forming the first film 3a and forming the second film 3b as disclosed in FIG. 2B. The first film 3a and the second film 3b are different from each other and may be selected from InP, InGaAs, InGaAsP, InAlAs, AlGaAs, and InAlGaAs, respectively. The forming of the reflective layer 3 may include a deposition process such as metal organic chemical vapor deposition (MOCVD), a molecular beam epitaxy (MBE), or a selective epitaxial growth (SEG) process.

Subsequently, a buffer layer 5 may be formed on the reflective layer 3. The buffer layer 5 may be the same n-type InP as the substrate 1. A grading layer 9 may be formed on the buffer layer 5. The grading layer 9 may be formed by sequentially stacking InGaAsP having various band gaps in multiple layers. An electric field control layer 11 may be formed on the grading layer 9. The electric field control layer 11 may be InP doped with silicon, for example. An electric field buffer layer 13 may be formed on the electric field control layer 11. The electric field buffer layer 13 may be, for example, InP with n-type or without n-type (or intrinsic). A first diffusion control layer 15, a second diffusion control layer 17, and a mask layer 19 may be sequentially stacked on the electric field buffer layer 13. The first diffusion control layer 15 may include, for example, InGaAs. The second diffusion control layer 17 may include a material different from the first diffusion control layer 15. The second diffusion control layer 17 may include, for example, InP. The mask layer 19 may include a silicon nitride film. In FIG. 3, thicknesses of the first diffusion control layer 15 and the second diffusion control layer 17 may be determined by considering depths of the subsequent impurity region 31 and the guard ring region 29.

Referring to FIG. 4, the mask layer 19 and the second diffusion control layer 17 may be sequentially etched to form a second opening 21 exposing the first diffusion control layer 15. As a result, the mask pattern 19p and the second diffusion control pattern 17p may be formed. The second opening 21 may have a circular shape in a plan view.

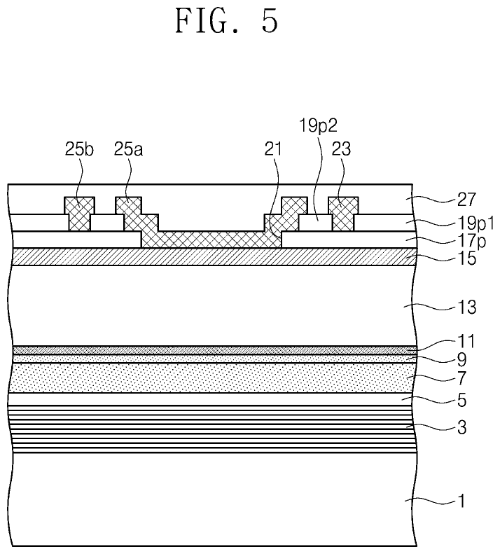

Referring to FIGS. 4 and 5, the mask pattern 19p may be patterned to form a first mask pattern 19p1 and a second mask pattern 19p2 separated from each other. A third opening 23 exposing the upper surface of the second diffusion control pattern 17p may be present between the first mask pattern 19p1 and the second mask pattern 19p2. The third opening 23 may have a circular ring shape in a plan view. Sidewalls of the second mask pattern 19p2 may not be aligned with sidewalls of the second diffusion control pattern 17p exposed in the second opening 21. In the state where the second opening 21 and the third opening 23 are formed, the impurity containing layer may be stacked and patterned to form a first impurity containing pattern 25a and a second impurity containing pattern 25b spaced apart from each other. The first impurity containing pattern 25a and the second impurity containing pattern 25b may be in contact with each other without being spaced apart from each other. For example, the first impurity containing pattern 25a and the second impurity containing pattern 25b may be doped with P-type impurities. The first impurity containing pattern 25a and the second impurity containing pattern 25b may include zinc phosphide (Zn₃P₂). A capping layer 27 may be formed to cover the first impurity containing pattern 25a and the second impurity containing pattern 25b. The capping layer 27 may be, for example, a silicon oxide film.

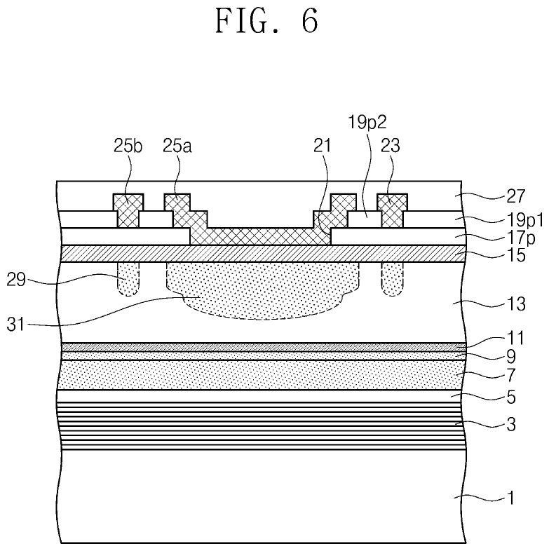

Referring to FIG. 6, as a heat treatment process is performed, P-type impurities, for example, zinc (Zn), included in the first impurity containing pattern 25a and the second impurity containing pattern 25b pass through the first diffusion control layer 15 and the second diffusion control pattern 17p to diffuse into the electric field buffer layer 13, thereby forming an impurity region 31 and a guard ring region 29. At this time, the heat treatment process may be performed for 10 minutes to 24 hours at a temperature of 350 to 1000° C., for example. Since impurities contained in the first impurity containing pattern 25a pass through only the first diffusion control layer 15 but impurities contained in the second impurity containing pattern 25b must pass through not only the first diffusion control layer 15 but also the second diffusion control pattern 17p, the impurity region 31 may be formed deeper than the guard ring region 29. The first diffusion control layer 15 may also be doped with the impurity by the heat treatment process. The capping layer 27 may prevent the impurity containing patterns 25a and 25b from being lost during the heat treatment process.

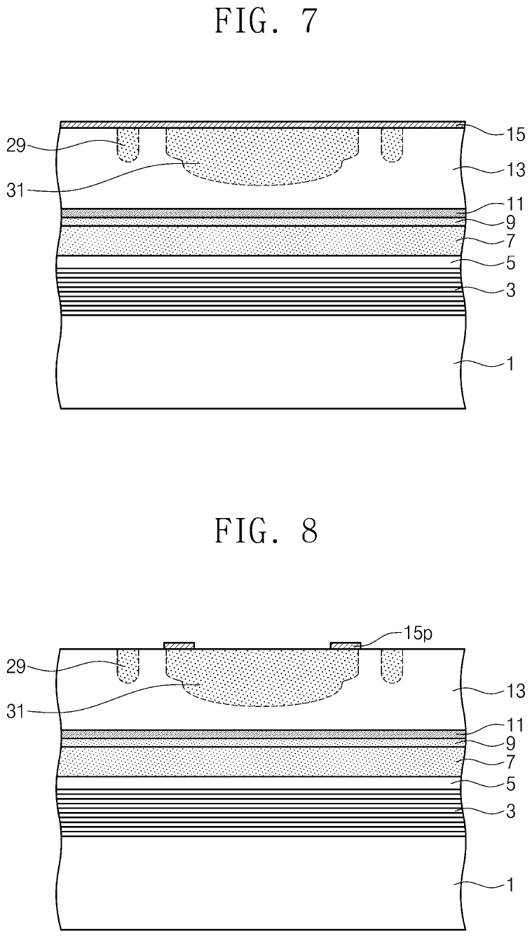

Referring to FIGS. 6 and 7, the capping layer 27, the first and second impurity containing patterns 25a and 25b, the first and second mask patterns 19p1 and 19p2, and the second diffusion control pattern 17p may be removed. In addition, a portion of the first diffusion control layer 15 may be removed to reduce the thickness.

Referring to FIGS. 7 and 8, an ohmic pattern 15p may be formed by patterning the first diffusion control layer 15. The ohmic pattern 15p may contact the impurity region 31. In addition, the guard ring region 29 may be exposed at this time.

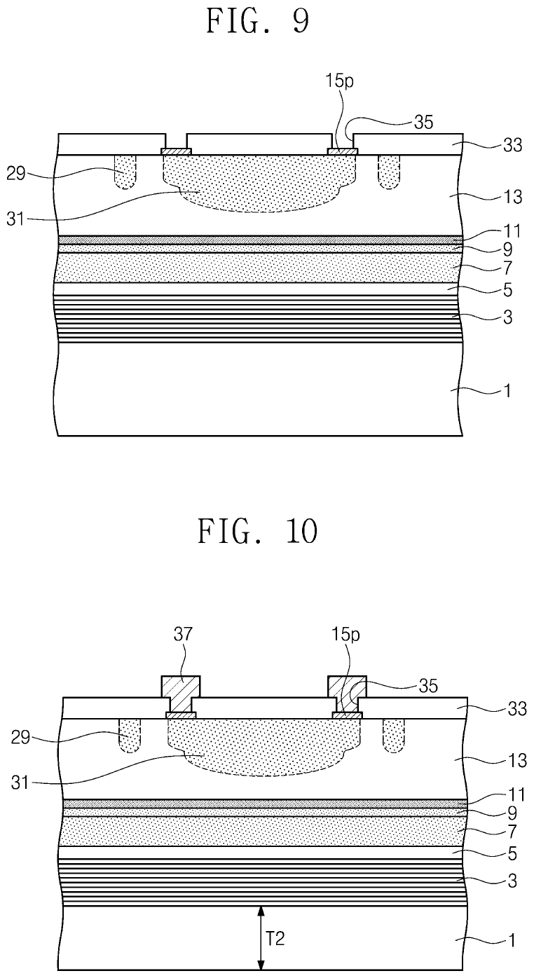

Referring to FIG. 9, a passivation film 33 may be formed on the electric field buffer layer 13. The passivation film 33 may be formed of a silicon nitride film, polyimide, or Bisbenzocyclotene (BCB). The passivation film 33 may be patterned to form a first opening 35 exposing the ohmic pattern 15p.

Referring to FIG. 10, a first electrode 37 contacting the ohmic pattern 15p may be formed through the first opening 35. As described with reference to FIG. 2C, the first electrode 37 may be formed to include an adhesive film 37a, a diffusion barrier film 37b, and an electrode pattern 37c. The thickness of the substrate 1 may be reduced to a second thickness T2 by performing lapping and/or polishing processes to partially remove the lower part of the substrate 1. Then, subsequently, the second electrode 39 may be formed on the lower surface of the substrate 1 with reference to FIG. 2A.

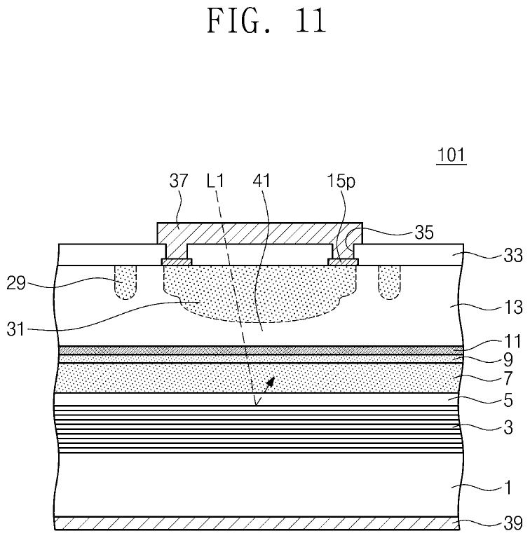

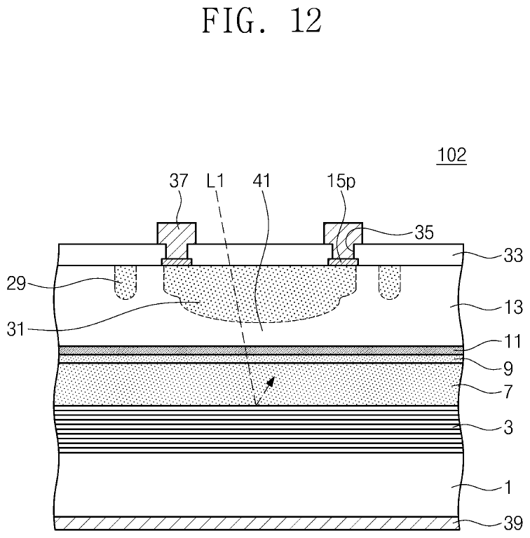

FIGS. 11 and 12 are cross-sectional views of a single photon detector according to embodiments of the inventive concept.

Referring to FIG. 11, in the single photon detector 101 according to the present example, the first electrode 37 may have a circular shape in a plan view. The first electrode 37 may be a transparent electrode such as indium tin oxide (ITO) or indium zinc oxide (IZO). Light L1 may pass through the first electrode 37. Other configurations may be the same as or similar to those described with reference to FIGS. 2A and 2B.

Alternatively, referring to FIG. 12, in the single photon detector 102 according to the present example, the reflective layer 3 may be in contact with the light absorption layer 7 without the buffer layer 5. Other configurations may be the same as or similar to those described with reference to FIGS. 2A to 2C.

The single photon detector according to the embodiments of the inventive concept may include a reflective layer interposed between the light absorption layer and the substrate, and may prevent the loss of photons and increase the detection efficiency.

The manufacturing method of the single photon detector according to the embodiments of the inventive concept can be easily embodied.

Although the exemplary embodiments of the inventive concept have been described, it is understood that the inventive concept should not be limited to these exemplary embodiments but various changes and modifications may be made by one ordinary skilled in the art within the spirit and scope of the inventive concept as hereinafter claimed.

What is claimed is:

1. A single photon detector comprising:
a substrate of a first conductivity type;
a light absorption layer on the substrate;
a grading layer and an electric field buffer layer sequentially stacked on the light absorption layer;
an impurity region of a second conductivity type disposed in the electric field buffer layer, the second conductivity type being opposite to the first conductivity type;
a first electrode disposed on the electric field buffer layer and electrically connected to the impurity region;
a reflective layer disposed between the light absorption layer and the substrate; and
a second electrode disposed below the substrate and electrically connected to the substrate.

2. The single photon detector of claim 1, wherein the reflective layer is a distributed Bragg reflector.

3. The single photon detector of claim 1, wherein the reflective layer comprises a structure in which a first film and a second film of different materials are alternately stacked, each of the first film and the second film being selected from InP, InGaAs, InGaAsP, InAlAs, AlGaAs, and InAlGaAs.

4. The single photon detector of claim 1, wherein the reflective layer has a reflectance of 90% or more.

5. The single photon detector of claim 1, further comprising a buffer layer interposed between the reflective layer and the light absorption layer,
wherein the buffer layer comprises a same material as the substrate.

6. The single photon detector of claim 1, further comprising an electric field control layer interposed between the grading layer and the electric field buffer layer,
wherein the electric field control layer comprises silicon.

7. The single photon detector of claim 1, further comprising a guard ring region of the second conductivity type disposed to be spaced apart from the impurity region in the electric field buffer layer,
wherein the guard ring region and the first electrode have a ring shape in a plan view.

8. The single photon detector of claim 1, further comprising an ohmic pattern disposed between the first electrode and the impurity region,
wherein the ohmic pattern has a ring shape in a plan view.

9. The single photon detector of claim 8, wherein the ohmic pattern is doped with zinc.

10. The single photon detector of claim 1, further comprising a passivation film covering a top surface of the electric field buffer layer,
wherein the first electrode is electrically connected to the impurity region through the passivation film,
wherein the first electrode has a circular shape in a plan view and is transparent.

11. The single photon detector of claim 1, wherein the first electrode comprises an adhesive layer, a diffusion barrier layer, and an electrode pattern that are sequentially stacked.

12. A manufacturing method of a single photon detector, the method comprising:
forming a reflective layer on a substrate of a first conductivity type;
forming a light absorption layer on the reflective layer;
forming a grading layer on the light absorption layer;
forming an electric field control layer on the grading layer;
forming an electric field buffer layer on the electric field control layer;
forming an impurity region of a second conductivity type opposite to the first conductivity type in the electric field buffer layer; and
forming a first electrode electrically connected to the impurity region on the electric field buffer layer.

13. The method of claim 12, wherein the forming of the reflective layer comprises performing a plurality of times a process cycle including forming a first film and forming a second film,
wherein each of the first film and the second film is selected from InP, InGaAs, InGaAsP, InAlAs, AlGaAs, and InAlGaAs, respectively, and the first film comprises a material different from a material of the second film.

14. The method of claim 12, further comprising forming a buffer layer interposed between the reflective layer and the light absorption layer,
wherein the buffer layer comprises a same material as the substrate.

15. The method of claim 12, wherein the electric field control layer comprises silicon.

16. The method of claim 12, wherein the forming of the impurity region comprises:
sequentially stacking a first diffusion control layer, a second diffusion control layer, and a mask layer on the electric field buffer layer;
patterning the mask layer and the second diffusion control layer to form a mask pattern and a second diffusion control pattern including a first opening exposing the first diffusion control layer;
forming an impurity containing layer in contact with the first diffusion control layer in the first opening; and
performing a heat treatment process to diffuse the impurities contained in the impurity containing layer into the electric field buffer layer through the first diffusion control layer.

17. The method of claim 16, further comprising forming a capping layer covering the impurity containing layer before performing the heat treatment process.

18. The method of claim 16, further comprising, after the forming of the impurity region,
removing the mask pattern and the second diffusion control pattern; and
patterning the first diffusion control layer to form an ohmic pattern.

19. The method of claim 12, further comprising forming a guard ring region of the second conductivity type to be spaced apart from the impurity region in the electric field buffer layer,
wherein the forming of the guard ring region is performed simultaneously with the forming of the impurity region.

20. The method of claim 12, further comprising:
removing a portion of a lower part of the substrate; and
forming a second electrode on the lower surface of the substrate.
